(19) United States
(12) Patent Application Publication
(10) Pub. No.: US 2024/0376629 A1
(43) Pub. Date: Nov. 14, 2024

(54) WAFER RECEIVER, ELECTROCHEMICAL POROSIFICATION APPARATUS AND METHOD USING SAME

(71) Applicant: SOCPRA SCIENCES ET GENIE S.E.C., Sherbrooke (CA)

(72) Inventors: Philippe-Olivier PROVOST, Sherbrooke (CA); Abderraouf BOUCHERIF, Sherbrooke (CA)

(21) Appl. No.: 18/692,194

(22) PCT Filed: Sep. 27, 2022
(86) PCT No.: PCT/CA2022/051428

§ 371 Date: Mar. 14, 2024

Related U.S. Application Data
(60) Provisional application No. 63/248,594, filed on Sep. 27, 2021.

(51) Int. Cl. C25F 7/00; C25F 3/12; H01L 21/306; H01L 21/67; H01L 21/683

(52) U.S. Cl. CPC C25F 7/00; C25F 3/12; H01L 21/30604; H01L 21/67075; H01L 21/6838

(57) ABSTRACT

There is described a wafer receiver for use in an electrochemical porosification process. The wafer receiver generally has an electrode body having a first flat surface, a second flat surface opposite the first flat surface, a groove recessed from the first flat surface and running within a central region of the electrode body, a seat extending annularly around the central region of the electrode body and recessed from the first flat surface, a conduit in fluid communication with the groove and connectable to a vacuum pump; and an annular sealing element received in the seat, the annular sealing element being made of a resilient material resistant to said electrochemical porosification process, the annular sealing element having a wafer receiving surface protruding from the first flat surface when received in the scat.

### FIELD

The improvements generally relate to semiconductor wafers and more particularly relate to electrochemical porosification processes to be performed on the semiconductor wafers.

### BACKGROUND

Electrochemical porosification is the process of making a porous layer into a semiconductor wafer such as a silicon wafer or a germanium wafer. Porous silicon or germanium layers that result from such processes have been found to be useful in a number of applications including microelectromechanical systems (MEMS), solar cells, distributed Bragg reflectors, microcavities, waveguides to name a few examples. The porosification process can be performed using an electrochemical porosification apparatus which contacts a back face of the semiconductor wafer to a first electrode, and exposes a front face of the semiconductor wafer to an etching solution, e.g., a solution containing hydrofluoric (HF) acid. A voltage is then applied between the first electrode and a second electrode immersed in the etching solution. When key parameters are set properly, as known in the art, pore growth by semiconductor dissolution is initiated where the semiconductor wafer is exposed to the etching solution. To maintain the semiconductor wafer in position within the etching solution, it is known to force the semiconductor wafer against the first electrode by pressing an annular member onto a peripheral region of the first face of the semiconductor wafer, thereby exposing a central region of the front face of the semiconductor wafer to the etching solution thanks to the hollowness of the annular member. Although existing electrochemical porosification apparatuses are satisfactory to a certain degree, there remains room for improvement.

### SUMMARY

It was found that there is a need in the industry for electrochemical porosification apparatuses and methods which avoid the obstruction of a portion of the front face of the semiconductor wafer and increase the area where pores can be grown. In addition, it was found that, at least in some circumstances, the force exerted by the annular member against the semiconductor wafer can undesirably deform it which can be detrimental when high quality porous semiconductor wafers are sought.

In accordance with a first aspect of the present disclosure, there is provided a wafer receiver for use in an electrochemical porosification process, the wafer receiver comprising: an electrode body having a first flat surface, a second flat surface opposite the first flat surface, a groove recessed from the first flat surface and running within a central region of the electrode body, a seat extending annularly around the central region of the electrode body and recessed from the first flat surface, a conduit in fluid communication with the groove and connectable to a vacuum pump; and an annular sealing element received in the seat, the annular sealing element being made of a resilient material resistant to said electrochemical porosification process, the annular sealing element having a wafer receiving surface protruding from the first flat surface when received in the seat; wherein, when a semiconductor wafer is received on the wafer receiving surface of the annular sealing element, the vacuum pump is activatable to form a vacuum sucking air out of the conduit and the groove pulling the semiconductor wafer towards the first flat surface, said pulling including compressing the annular sealing element to level the wafer receiving surface with the first flat surface, and bringing a back face of the semiconductor wafer and the first flat surface in physical contact with one another.

Further in accordance with the first aspect of the present disclosure, the resilient material can for example be a fluoroelastomer material.

Still further in accordance with the first aspect of the present disclosure, the resilient material can for example be a polytetrafluoroethylene (PTFE) material.

Still further in accordance with the first aspect of the present disclosure, the groove can for example include a plurality of grooves in fluid communication at least with the conduit.

Still further in accordance with the first aspect of the present disclosure, the electrode body can for example be made of a corrosion-resistant material.

Still further in accordance with the first aspect of the present disclosure, in a rest position, the wafer receiving surface can for example have a plane being spaced apart from a plane of the first flat surface of the electrode body by a spacing.

Still further in accordance with the first aspect of the present disclosure, the spacing can for example range between about 0.5 mm and 3 mm, preferably between about 1 mm and 2 mm and most preferably between about 1 mm and 1.5 mm.

Still further in accordance with the first aspect of the present disclosure, the annular sealing element can for example have a rectangular cross-sectional shape.

Still further in accordance with the first aspect of the present disclosure, the annular sealing element can for example have an outer surface and a core extending within the outer surface, the outer surface being resistant to the electrochemical porosification process and the core being made of a resilient material.

In accordance with a second aspect of the present disclosure, there is provided an electrochemical porosification apparatus comprising: a container defining an inner cavity; a first electrode positioned within the inner cavity; a wafer receiver positioned within the inner cavity and spaced apart from the first electrode, the wafer receiver having: an electrode body having a first flat surface, a second flat surface opposite the first flat surface, a groove recessed from the first flat surface and running within a central region of the electrode body, a seat extending annularly around the central region of the electrode body and recessed from the first flat surface, a conduit in fluid communication with the groove and connectable to a vacuum pump; and an annular sealing element received in the seat, the annular sealing element being made of a resilient material resistant to acid, the annular sealing element having a wafer receiving surface protruding from the first flat surface when received in the seat; a vacuum pump in fluid communication with the conduit and activatable for creating a vacuum sucking air out of the conduit and the groove pulling a semiconductor wafer received on the wafer receiving surface of the annular sealing element towards the first flat surface, said pulling including compressing the annular sealing element to level the wafer receiving surface with the first flat surface, and bringing a back face of the semiconductor wafer and the first flat surface in physical contact with one another; an etching solution source in fluid communication with the inner cavity and being configured for immersing at least a portion of the inner cavity with an etching solution; and a current source configured to propagate an electrical current across the etching solution using the first electrode and the electrode body, said current and said etching solution making pores within an exposed surface of the semiconductor wafer.

Further in accordance with the second aspect of the present disclosure, the resilient material can for example be a fluoroelastomer material.

Still further in accordance with the second aspect of the present disclosure, the resilient material can for example be a polytetrafluoroethylene (PTFE) material.

Still further in accordance with the second aspect of the present disclosure, the groove can for example include a plurality of grooves in fluid communication at least with the conduit.

Still further in accordance with the second aspect of the present disclosure, the electrode body can for example be made of a corrosion-resistant material.

Still further in accordance with the second aspect of the present disclosure, in a rest position, the wafer receiving surface can for example have a plane being spaced apart from a plane of the first flat surface of the electrode body by a spacing ranging between about 1 mm and 5 mm, preferably between about 1 mm and 3 mm and most preferably between about 1 mm and 2 mm.

Still further in accordance with the second aspect of the present disclosure, the annular sealing element can for example have a rectangular cross-sectional shape.

In accordance with a third aspect of the present disclosure, there is provided a method of performing an electrochemical porosification process to a semiconductor wafer, the method comprising: receiving a back face of the semiconductor wafer on an annular sealing element, the annular sealing element being resistant to an etching solution and being resilient; creating a vacuum in a cavity bounded by the back face of the semiconductor element, the vacuum sucking air out of the cavity pulling the semiconductor wafer towards a flat surface of an electrode body, said pulling including compressing the annular sealing element to level a wafer receiving surface of the annular sealing element with the flat surface and bringing the back face of the wafer and the flat surface in physical contact with one another; while maintaining said vacuum, immersing an exposed face of the semiconductor wafer in an etching solution and, using another electrode spaced apart from the electrode body, propagating an electrical current across the etching solution, the etching solution and the electrical current making pores within the exposed surface of the semiconductor wafer.

Further in accordance with the third aspect of the present disclosure, the method can for example further comprise, upon removing said vacuum, said annular sealing element expanding and moving the semiconductor wafer away from the electrode body.

Still further in accordance with the third aspect of the present disclosure, the semiconductor wafer can for example be one of a silicon wafer and a germanium wafer.

Still further in accordance with the third aspect of the present disclosure, the etching solution can for example include an hydrofluoric (HF) solution.

In accordance with a fourth aspect of the present disclosure, there is provided a wafer receiver for use in an electrochemical porosification process, the wafer receiver comprising: an electrode body having a first flat surface, a second flat surface opposite the first flat surface, a groove recessed from the first flat surface and running within a central region of the electrode body, a seat extending annularly around the central region of the electrode body and recessed from the first flat surface, a conduit in fluid communication with the groove and connectable to a vacuum pump; and an annular sealing element received in the seat, the annular sealing element being made of a resilient material resistant to said electrochemical porosification process, the annular sealing element having a wafer receiving surface protruding from the first flat surface when received in the seat.

In accordance with a fifth aspect of the present disclosure, there is provided a container defining an inner cavity; a first electrode positioned within the inner cavity; a wafer receiver positioned within the inner cavity and spaced apart from the first electrode, the wafer receiver having: an electrode body having a first flat surface, a second flat surface opposite the first flat surface, a groove recessed from the first flat surface and running within a central region of the electrode body, a seat extending annularly around the central region of the electrode body and recessed from the first flat surface, a conduit in fluid communication with the groove and connectable to a vacuum pump; and an annular sealing element received in the seat, the annular sealing element being made of a resilient material resistant to acid, the annular sealing element having a wafer receiving surface protruding from the first flat surface when received in the seat; a vacuum pump in fluid communication with the conduit and activatable for creating a vacuum within the conduit pulling the semiconductor wafer against the annular sealing element; an etching solution source in fluid communication with the inner cavity and being configured for immersing at least a portion of the inner cavity with an etching solution; and a current source configured to propagate an electrical current across the etching solution using the first electrode and the electrode body.

In this disclosure, the term “resilient material” can be any material which can spring back into its original shape after bending, stretching or being compressed. In the context of the annular sealing element, it is understood that the resilient material of the annular sealing element will be only elastically deformed when sandwiched between the semiconductor wafer and the electrode body by way of the vacuum. Once the vacuum is shut off, the resilient material of the annular sealing element springs back into its pre-vacuum shape.

Many further features and combinations thereof concerning the present improvements will appear to those skilled in the art following a reading of the instant disclosure.

### DESCRIPTION OF THE FIGURES

In the figures,

FIG. 1 is a sectional oblique view of an example of an electrochemical porosification apparatus, shown with an example wafer receiver, in accordance with one or more embodiments;

FIG. 2 is an oblique view of the wafer receiver of FIG. 1, in accordance with one or more embodiments;

FIG. 2A is a sectional view of an annular sealing element of the wafer receiver of FIG. 2, taken along section 2A-2A, in accordance with one or more embodiments;

FIG. 3 is a sectional oblique view of the electrochemical porosification apparatus of FIG. 1, shown a semiconductor wafer received therein, in accordance with one or more embodiments;

FIG. 4A is a sectional view of an example of a wafer receiver receiving a semiconductor wafer, shown prior to vacuuming, in accordance with one or more embodiments;

FIG. 4B is a sectional view of the wafer receiver of FIG. 4A, shown during vacuuming, in accordance with one or more embodiments; and

FIG. 5 is a flow chart of a method of performing an electrochemical porosification process using a wafer holder, in accordance with one or more embodiments.

### DETAILED DESCRIPTION

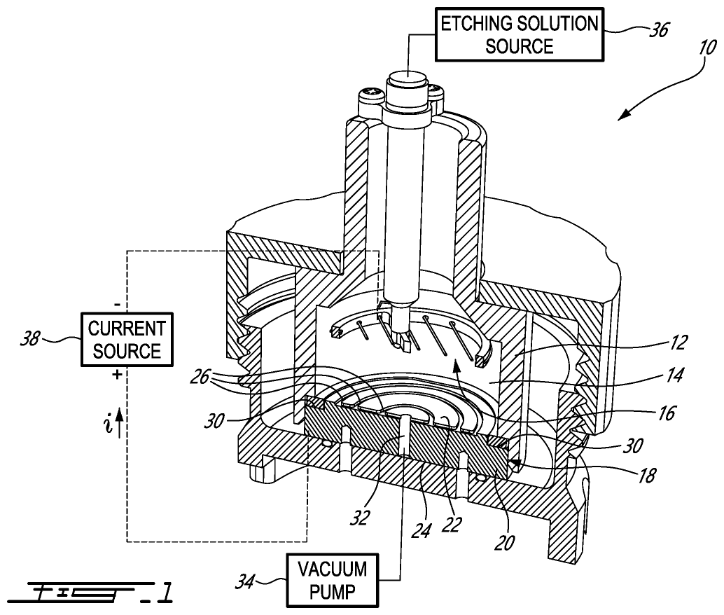

FIG. 1 shows a cross-sectional view of an example of an electrochemical porosification apparatus 10, in accordance with an embodiment. As depicted, the apparatus 10 has a container 12 defining an inner cavity 14, a first electrode 16 positioned within the inner cavity 14, and a wafer receiver 18 also positioned within the inner cavity 14 and spaced apart from the first electrode 16. The wafer receiver 18 has an electrode body 20 having a first flat surface 22, a second flat surface 24 opposite the first flat surface 22, and grooves 26 recessed from the first flat surface 22 and running within a central region of the electrode body 20. The wafer receiver 18 is also provided with a seat 30 extending annularly around the central region of the electrode body 20 and recessed from the first flat surface 22. As illustrated, a conduit 32 extends within the electrode body and is in fluid communication with the grooves 26. As shown, the conduit 32 is connectable to a vacuum pump 34. The apparatus 10 has a vacuum pump 34 which is connectable to the conduit 32 of the electrode body 20. The vacuum pump 34 is activatable for creating a vacuum in at least a given portion of the inner cavity 14 of the container via the conduit 32 and the grooves 26. The apparatus 10 is provided with an etching solution source 36 in fluid communication with the inner cavity 14 and being configured for immersing at least a portion of the inner cavity 14 with an etching solution (not shown). A current source 38 is also provided to propagate a current i between the first electrode 16 and the wafer receiver 18 and across the etching solution when the inner cavity 14 is partially or wholly filled with the etching solution.

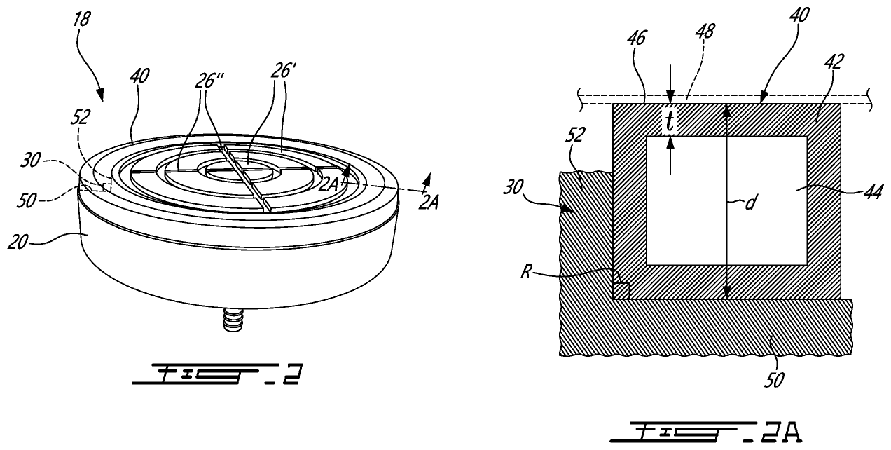

As best shown in FIG. 2, the wafer receiver 18 has an annular sealing element 40 received in the seat 30 of the electrode body 20. The annular sealing element 40 is resistant to the etching solution, and more specifically acid-resistant in this embodiment. In addition, the annular sealing element 40 is resilient in that it can be compressed upon the application of a force thereon and can take its original shape upon release of the force. Accordingly, when the inner cavity is filled with the etching solution, the annular sealing element 40 remains in good condition and performs its functions. In this specific example, the grooves include three annular grooves 26′ of increasing diameter, and two linear grooves 26″ extending perpendicularly with one another. The linear grooves 26″ fluidly connect each one of the three annular grooves 26′ with one another. The groove 26′ and 26″ can have any other suitable shape, as long as they run along a central region of the electrode body 20. The electrode body 20 can be made of any electrically conducting material. For instance, the electrode body can be made of copper, graphite, titanium, brass, silver, mixed metal oxide, platinum, glassy carbon, and the like. The electrode body can be made of graphoil, graphite-plastic composite, silicon, diamond liked coated silicon and the like in embodiments where the apparatus is to be clean-room compliant. It was found convenient to use graphoil for the electrode body in some embodiments as it is a highly conductive material in addition to being corrosion-resistant.

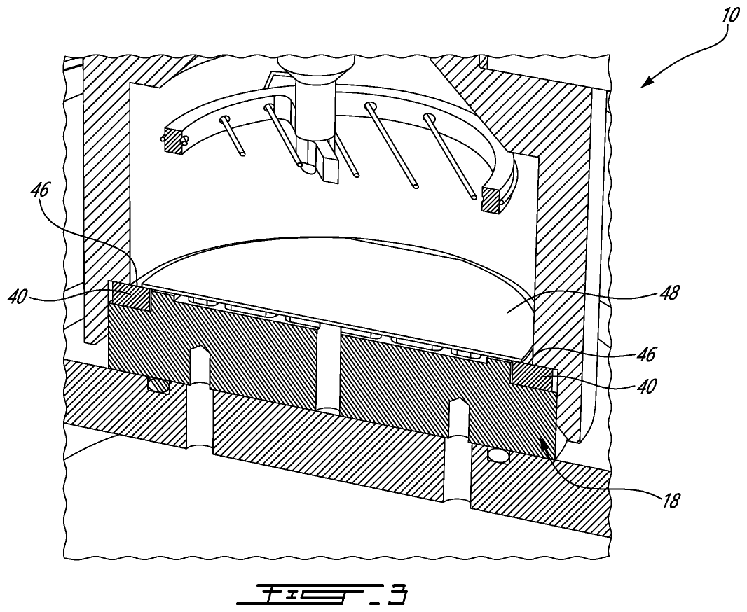

Referring now to the specific embodiment shown in FIG. 2A, the annular sealing element 40 is provided with an outer surface 42 and a core 44 extending within the outer surface 42. In these embodiments, the outer surface 42 can be made of an acid-resistant material while the core 44 can be made of a resilient material. Additionally or alternatively, the outer surface 42 can be resilient whereas that the core 44 can be acid-resistant. In some embodiments, the outer surface can be provided in the form of a jacket or a sheath. In some embodiments, the annular sealing element is made of a single piece of material which is selected to be resilient in addition to being acid-resistant. As shown, the annular sealing element 40 has a wafer receiving surface 46 onto which a semiconductor wafer 48 (shown in dashed line) can be received during use. FIG. 3 shows the apparatus 10 in which the wafer receiver 18, and more specifically the wafer receiving surface 46 of the annular sealing element 40, receives the semiconductor wafer 48. In some embodiments, the outer surface 42 is made of a vulcanized, polymerized or otherwise solidified fluoroelastomer material such as Viton™. In some embodiments, the core 44 is made of an emulsified fluoroelastomer material such as Viton™ foam. Such fluoroelastomers have been known to be acid-resistant, and more specifically resistant to hydrofluoric (HF) acid. Other acid-resistant materials can be used in some other embodiments. For instance, the core can be made of polytetrafluoroethylene (PTFE) (Teflon™) foam material which is another example of an acid-resistant material.

Referring back to FIGS. 2 and 2A, it is intended that the annular sealing element 40 is sized and shaped to be snugly received in the seat 30 of the electrode body 40. For instance, in this example, the seat 30 forms a right angle R between a radially extending wall 50 and axially extending wall 52 of the electrode body 20. Accordingly, as shown, the annular sealing element 40 has a rectangular cross-sectional shape which fits snugly into the seat 30 when received therein. In some embodiments, the annular sealing element 40 has a cross-sectional dimension d ranging between about 1 mm and 20 mm, preferably between about 5 mm and 15 mm and preferably between about 7 mm and 12 mm. In some embodiments, the outer surface 42 of the annular sealing element 40 has a thickness t ranging between about 0.1 mm and 5 mm, preferably between about 0.1 mm and 3 mm and preferably between about 0.1 mm and 1 mm.

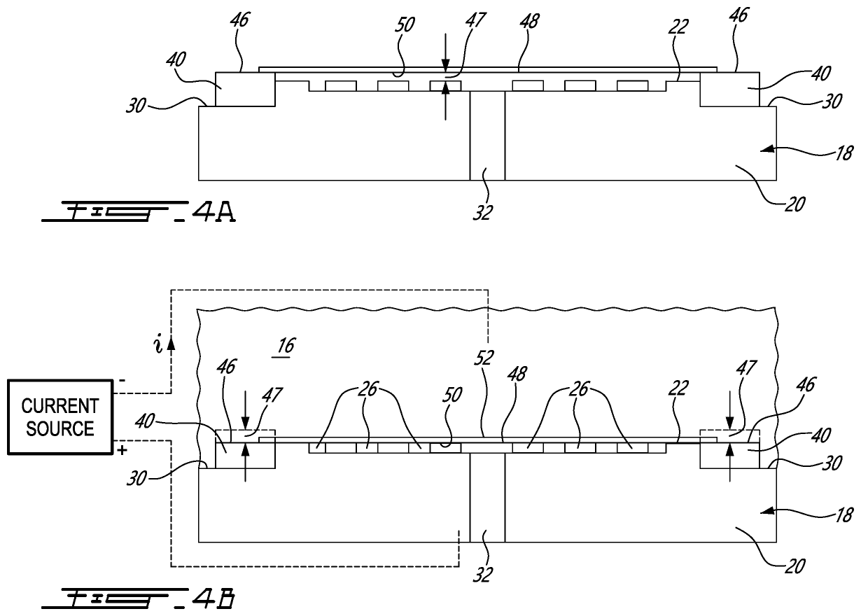

FIG. 4A shows that, in a rest state, the wafer receiving surface 46 protrudes from the first flat surface 22 when the annular sealing element 40 is received in the seat 30 of the electrode body 20. A gap 47 is thus present between the semiconductor wafer 48 and the first flat surface 22 of the electrode body 20 in the rest state. In some embodiment, the gap 47 can range between about 1 mm and 5 mm, preferably between about 1 mm and 3 mm and most preferably between about 1 mm and 2 mm. Accordingly, upon creating a vacuum in the conduit 32, such as shown in FIG. 4B, air is sucked out of the conduit 32 and the grooves 26 thereby pulling the semiconductor wafer 48 towards the first flat surface 22 of the electrode body 20. By doing so, the annular sealing element 40 is compressed by way of the movement of the semiconductor wafer 48 to level the wafer receiving surface 46 with the first flat surface 22, which in turn brings a back face 50 of the semiconductor wafer 48 and the first flat surface 22 in physical contact with one another. As can be appreciated, in such a vacuum state, the inner cavity can be filled with the etching solution, and when an electrical current i is propagated between the first electrode and the electrode body, across the etching solution and the semiconductor wafer, the electrical current I and the etching solution collectively make pores within an exposed surface 52 of the semiconductor wafer 48. It is intended that the difference in thickness of the annular sealing element between the rest state and the vacuum state preferably corresponds to the gap 47 introduced with reference to FIG. 4A.

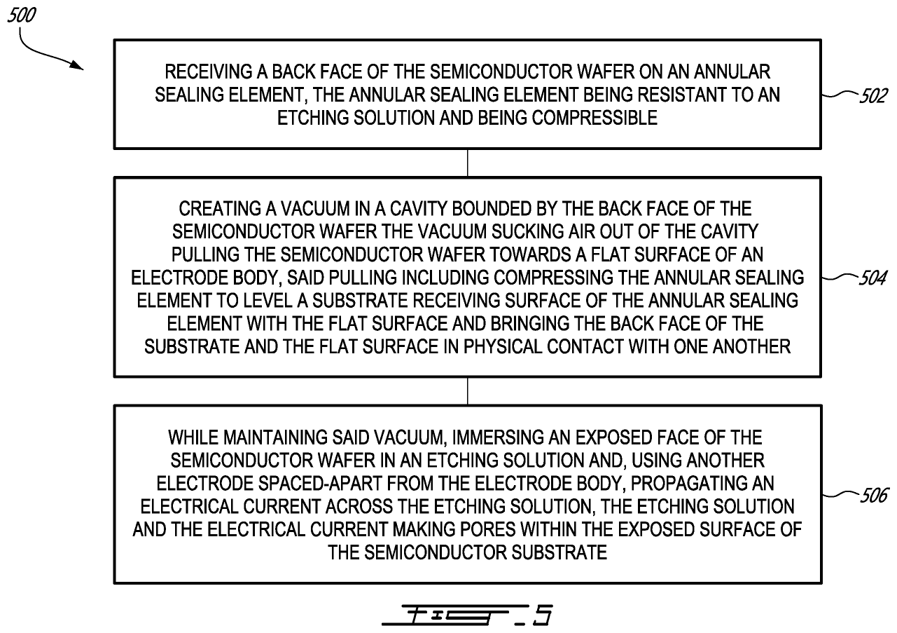

FIG. 5 shows an example of a method of performing an electrochemical porosification process to a semiconductor wafer.

At step 502, a back face of the semiconductor wafer is received on an annular sealing element. The semiconductor wafer can be a silicon wafer, a germanium wafer, a silicium carbide (SiC) wafer, an indium phosphide (InP) wafer, a gallium arsenide (GaAs) wafer, a gallium nitride (GaN) wafer or any other suitable semiconductor wafer. For instance, the wafer can involve any type of semiconductor material including, but not limited to, silicon, silicon nitride (SiN), silicon-on-insulator (SOI), silicon nitride (Si₃N₄), silicon carbide (SiC), gallium nitride (GaN), indium gallium arsenide (InGaAs), lithium niobate (LiNbO₃), indium antimonide (InSb), mercury cadmium telluride (MCT), indium arsenide (InAs), lead selenide (PbSe), lead sulfide (PbS), chalcogenide-based materials such as sulphide-based materials, selenide-based materials, telluride-based materials, any doped semiconductor including n-type doping, p-type doping, germanium doping, silicon doping, boron doping, arsenic doping, carbon doping, helium doping, antimony doping, and/or active laser material doping such as rare earth ion doping like erbium, ytterbium, quantum dot, gas or any combination thereof. As discussed above, the annular sealing element is resistant to an etching solution. The typical etching solution generally has HF acid or other types of acids, accordingly the annular sealing element is acid-resistant. The annular sealing element is also resilient, as discussed above. The compressibility of the annular sealing element depends on its construction and/or composition. For instance, the annular sealing element can have an outer surface made of a solid material and a core made of a resilient material filling the outer surface. In some embodiments, the solid material of the outer surface is a fluoroelastomer such as Viton™. The resilient material can be a fluoroelastomer foam such as Viton™ foam. Other acid-resistant materials can be used in some other embodiments.

At step 504, a vacuum is created in a cavity bounded by the back face of the semiconductor wafer. The vacuum sucks air out of the cavity thereby pulling the semiconductor wafer towards a flat surface of an electrode body. The pulling in turn compresses the annular sealing element to level a wafer receiving surface of the annular sealing element with the flat surface. By doing so, the back face of the wafer and the flat surface are brought in physical contact with one another. It is intended that the compressibility of the annular sealing element is enough to avoid any bending of the semiconductor wafer as the vacuum pulls it towards the electrode body.

At step 506, while maintaining the vacuum of step 504, an exposed face of the semiconductor wafer is immersed in an etching solution and, using another electrode spaced apart from the electrode body, an electrical current is propagated across the etching solution. As in conventional porosification processes, the etching solution and the electrical current make pores within the exposed surface of the semiconductor wafer. In this way, the entirety of the exposed face of the semiconductor wafer can be porosificated at once.

In some embodiments, upon removing the vacuum created at step 504, and maintained at step 506, the annular sealing element expands and moves the semiconductor wafer away from the electrode body. Then, the semiconductor wafer may be pulled away from the annular sealing element.

As can be understood, the examples described above and illustrated are intended to be exemplary only. For instance, although the electrode body is shown with a plurality of grooves, other electrode bodies can have only a single groove extending within a central region thereof. The scope is indicated by the appended claims.

What is claimed is:

1. A wafer receiver for use in an electrochemical porosification process, the wafer receiver comprising:
an electrode body having a first flat surface, a second flat surface opposite the first flat surface, a groove recessed from the first flat surface and running within a central region of the electrode body, a seat extending annularly around the central region of the electrode body and recessed from the first flat surface, a conduit in fluid communication with the groove and connectable to a vacuum pump; and
an annular sealing element received in the seat, the annular sealing element being made of a resilient material resistant to said electrochemical porosification process, the annular sealing element having a wafer receiving surface protruding from the first flat surface when received in the seat;
wherein, when a semiconductor wafer is received on the wafer receiving surface of the annular sealing element, the vacuum pump is activatable to form a vacuum sucking air out of the conduit and the groove pulling the semiconductor wafer towards the first flat surface, said pulling including compressing the annular sealing element to level the wafer receiving surface with the first flat surface, and bringing a back face of the semiconductor wafer and the first flat surface in physical contact with one another.

2. The wafer receiver of claim 1 wherein the resilient material is a fluoroelastomer material.

3. The wafer receiver of claim 1 wherein the resilient material is a polytetrafluoroethylene (PTFE) material.

4. The wafer receiver of claim 1 wherein the groove includes a plurality of grooves in fluid communication at least with the conduit.

5. The wafer receiver of claim 1 wherein the electrode body is made of a corrosion-resistant material.

6. The wafer receiver of claim 1 wherein, in a rest position, the wafer receiving surface has a plane being spaced apart from a plane of the first flat surface of the electrode body by a spacing.

7. The wafer receiver of claim 6 wherein the spacing ranges between about 0.5 mm and 3 mm, preferably between about 1 mm and 2 mm and most preferably between about 1 mm and 1.5 mm.

8. The wafer receiver of claim 1 wherein the annular sealing element has a rectangular cross-sectional shape.

9. The wafer receiver of claim 1 wherein the annular sealing element has an outer surface and a core extending within the outer surface, the outer surface being resistant to the electrochemical porosification process and the core being made of a resilient material.

10. An electrochemical porosification apparatus comprising:
a container defining an inner cavity;
a first electrode positioned within the inner cavity;
a wafer receiver positioned within the inner cavity and spaced apart from the first electrode, the wafer receiver having:
an electrode body having a first flat surface, a second flat surface opposite the first flat surface, a groove recessed from the first flat surface and running within a central region of the electrode body, a seat extending annularly around the central region of the electrode body and recessed from the first flat surface, a conduit in fluid communication with the groove and connectable to a vacuum pump; and
an annular sealing element received in the seat, the annular sealing element being made of a resilient material resistant to acid, the annular sealing element having a wafer receiving surface protruding from the first flat surface when received in the seat;
a vacuum pump in fluid communication with the conduit and activatable for creating a vacuum sucking air out of the conduit and the groove pulling a semiconductor wafer received on the wafer receiving surface of the annular sealing element towards the first flat surface, said pulling including compressing the annular sealing element to level the wafer receiving surface with the first flat surface, and bringing a back face of the semiconductor wafer and the first flat surface in physical contact with one another;
an etching solution source in fluid communication with the inner cavity and being configured for immersing at least a portion of the inner cavity with an etching solution; and
a current source configured to propagate an electrical current across the etching solution using the first electrode and the electrode body, said current and said etching solution making pores within an exposed surface of the semiconductor wafer.

11. The electrochemical porosification apparatus of claim 10 wherein the resilient material is a fluoroelastomer material.

12. The electrochemical porosification apparatus of claim 10 wherein the resilient material is a polytetrafluoroethylene (PTFE) material.

13. The electrochemical porosification apparatus of claim 10 wherein the groove includes a plurality of grooves in fluid communication at least with the conduit.

14. The electrochemical porosification apparatus of claim 10 wherein the electrode body is made of a corrosion-resistant material.

15. The electrochemical porosification apparatus of claim 10 wherein, in a rest position, the wafer receiving surface has a plane being spaced apart from a plane of the first flat surface of the electrode body by a spacing ranging between about 1 mm and 5 mm, preferably between about 1 mm and 3 mm and most preferably between about 1 mm and 2 mm.

16. The electrochemical porosification apparatus of claim 10 wherein the annular sealing element has a rectangular cross-sectional shape.

17. A method of performing an electrochemical porosification process to a semiconductor wafer, the method comprising:
receiving a back face of the semiconductor wafer on an annular sealing element, the annular sealing element being resistant to an etching solution and being resilient;
creating a vacuum in a cavity bounded by the back face of the semiconductor wafer, the vacuum sucking air out of the cavity pulling the semiconductor wafer towards a flat surface of an electrode body, said pulling including compressing the annular sealing element to level a wafer receiving surface of the annular sealing element with the flat surface and bringing the back face of the wafer and the flat surface in physical contact with one another;
while maintaining said vacuum, immersing an exposed face of the semiconductor wafer in an etching solution and, using another electrode spaced apart from the electrode body, propagating an electrical current across the etching solution, the etching solution and the electrical current making pores within the exposed surface of the semiconductor wafer.

18. The method of claim 17 further comprising, upon removing said vacuum, said annular sealing element expanding and moving the semiconductor wafer away from the electrode body.

19. The method of claim 17 wherein the semiconductor wafer is one of a silicon wafer and a germanium wafer.

20. The method of claim 17 wherein the etching solution includes an hydrofluoric (HF) solution.
